(19) United States
(12) Patent Application Publication
(10) Pub. No.: US 2024/0355693 A1
(43) Pub. Date: Oct. 24, 2024

(54) SEMICONDUCTOR DEVICE, SEMICONDUCTOR MODULE, AND METHOD FOR MANUFACTURING SEMICONDUCTOR MODULE

(71) Applicant: Kabushiki Kaisha Toshiba, Tokyo (JP)

(72) Inventors: Shogo MINAMI, Yokohama Kanagawa (JP); Tomohiro IGUCHI, Kawasaki Kanagawa (JP); Katsuya SATO, Yokohama Kanagawa (JP); Keiichiro MATSUO, Yokohama Kanagawa (JP)

(21) Appl. No.: 18/630,859

(22) Filed: Apr. 9, 2024

(30) Foreign Application Priority Data
Apr. 24, 2023 (JP) 2023-071123

(51) Int. Cl. H01L 23/31; H01L 23/00; H01L 23/26; H01L 23/29

(52) U.S. Cl. CPC H01L 23/3135; H01L 23/26; H01L 23/296; H01L 24/48; H01L 2224/48175; H01L 2224/48458; H01L 2924/1811; H01L 2924/186; H01L 2924/3511

(57) ABSTRACT

According to one embodiment, a semiconductor device includes a semiconductor element on a substrate. A first surface of the semiconductor element faces away from the substrate and a second surface faces the substrate. A first surface electrode is on the first surface of the semiconductor element. A bonding wire is connected to the first surface electrode at a bonding portion. A first sealing member covers the bonding portion. A second sealing member covers a portion of the first surface electrode outside the bonding portion. A third sealing member covers the first sealing member and the second sealing member.

### CROSS-REFERENCE TO RELATED APPLICATION

This application is based upon and claims the benefit of priority from Japanese Patent Application No. 2023-071123, filed Apr. 24, 2023, the entire contents of which are incorporated herein by reference.

### FIELD

Embodiments described herein relate generally to a semiconductor device, a semiconductor module, and a method for manufacturing a semiconductor module.

### BACKGROUND

A semiconductor module of a certain type usually includes a substrate having a conductor pattern thereon. A semiconductor element is mounted on the substrate with a rear (backside) surface electrode bonded to the conductor pattern on the substrate. The semiconductor element has a front surface electrode on an opposite side of the element from the rear surface electrode. A bonding wire electrically connects the front surface electrode to the conductor pattern or the like on the substrate. Generally, a semiconductor element is sealed inside a thermosetting resin or other sealing material. The sealing material provides moisture resistance to provide the element with a more stable performance in high temperature and high humidity environments. However, when the semiconductor element is repeatedly energized (that is, turned on/off), the sealing material will be repeatedly thermally expanded and shrunk (experience a thermal cycling event) due to the heat generation by the semiconductor element, potentially causing a problem with the sealing material being peeled off from (or otherwise released from) the front surface electrode and the bonding between the bonding wire and the front surface electrode or the like may be broken, resulting in poor or open connections.

In view of the above, there is a demand for a semiconductor module having higher reliability with respect to the bonding between bonding wires and the semiconductor elements and/or and the substrate conductor pattern while still sufficiently providing the required moisture resistance for the semiconductor element.

### BRIEF DESCRIPTION OF THE DRAWINGS

FIG. 1 is a cross-sectional view of a semiconductor module according to a first embodiment.

FIG. 2 depicts aspects of a method for manufacturing a semiconductor module according to a first embodiment.

FIGS. 3A and 3B are schematic cross sectional views of a semiconductor module depicting an aspect of a method for manufacturing a semiconductor module according to a first embodiment.

FIGS. 4A and 4B are schematic cross sectional views of a semiconductor module depicting an aspect of a method for manufacturing a semiconductor module according to a first embodiment.

FIG. 5 is a cross-sectional view of a semiconductor module according to a comparative example.

FIG. 6 depicts a comparison of cumulative inelastic strain applied to the bonding portion of a bonding wire to the normal stress applied to a second sealing member 5 in different examples.

FIG. 7 is a cross-sectional view of a semiconductor module according to a second embodiment.

FIG. 8 depicts aspects of a method for manufacturing a semiconductor module according to a second embodiment.

### DETAILED DESCRIPTION

Embodiments relate to a semiconductor module providing high moisture resistance and high reliability.

In general, according to one embodiment, a semiconductor device includes a semiconductor element on a substrate. A first surface of the semiconductor element faces away from the substrate and a second surface faces the substrate. A first surface electrode is on the first surface of the semiconductor element. A bonding wire is connected to the first surface electrode at a bonding portion. A first sealing member covers the bonding portion. A second sealing member covers a portion of the first surface electrode outside the bonding portion. A third sealing member covers the first sealing member and the second sealing member.

Hereinafter, certain examples of a semiconductor module and a method for manufacturing a semiconductor module will be described with reference to the drawings. In the present specification, description concerning a front surface refers to a surface facing away from a mounting surface or substrate and description concerning a rear surface refers toward a surface facing towards a mounting surface or substrate.

### First Embodiment

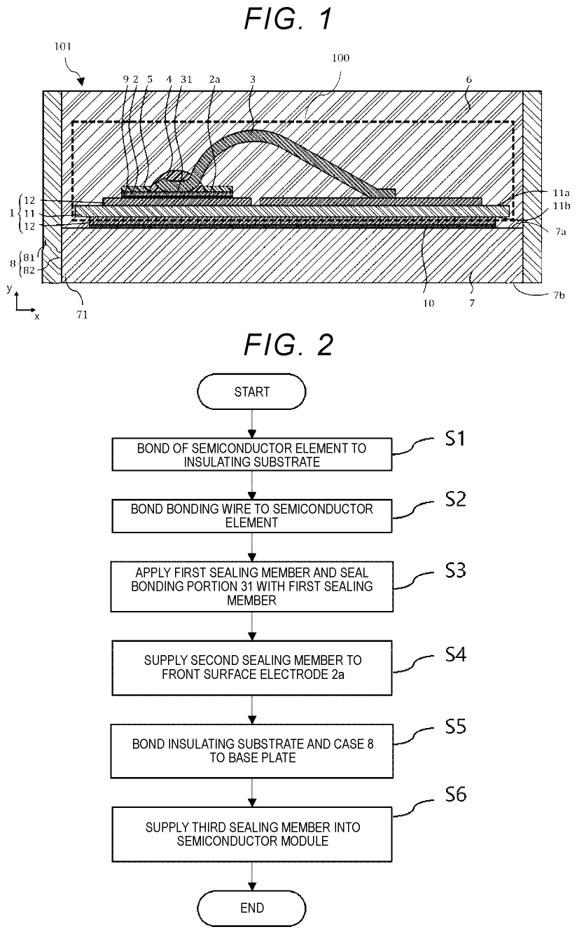

A semiconductor module and a method for manufacturing a semiconductor module of a first embodiment will be described with reference to FIGS. 1 to 5. First, a structure of a semiconductor module according to the first embodiment will be described. FIG. 1 shows a cross-sectional view of a semiconductor module according to the first embodiment. As shown in FIG. 1, a semiconductor device 100 includes a substrate 1, a semiconductor element 2 provided on the substrate 1 and having a front surface electrode 2a and a rear surface electrode, a bonding wire 3 connected to the front surface electrode 2a provided on the semiconductor element 2, a first sealing member 4 that covers a bonding portion between the front surface electrode 2a and the bonding wire 3, and a second sealing member 5 that is in contact with the first sealing member 4 around the first sealing member 4. In addition, the semiconductor module 101 includes a base plate 7 on which the semiconductor device 100 is placed and which removes heat of the semiconductor element 2, and a case 8 which is provided on an outer periphery of the base plate 7 and surrounds the periphery so that the entire semiconductor device 100 placed on the base plate 7 can be sealed with a third sealing member 6.

The substrate 1 includes an insulating layer 11 and a conductor pattern 12. The substrate 1 can have a structure in which insulating layers 11 and conductor patterns 12 are stacked one on the other. A plurality of conductor patterns 12 can be provided on the insulating layer 11 with the conductor patterns 12 being electrically insulated from each other by spacing and/or by a portion of an insulating layer 11. As the insulating layer 11, silicon nitride (SiN), alumina (Al₂O₃), or aluminum nitride (AlN) can be used. The insulating layer 11 has a front surface 11a and a rear surface 11b. The conductor patterns 12 can be provided on both the front surface 11a and the rear surface 11b. For the conductor pattern 12, copper (Cu) and/or aluminum (Al) can be used.

The semiconductor element 2 has the front surface electrode 2a on a surface opposite to the substrate 1. The semiconductor element 2 may comprise silicon, silicon carbide, or gallium nitride.

As the front surface electrode 2a, for example, an alloy of aluminum (Al) and copper (Cu) including silicon can be used. The front surface electrode 2a is electrically connected to an active region of the semiconductor element 2.

A bonding wire 3 is to be connected to the front surface electrode 2a. In some examples, the front surface electrode 2a may have a cover layer, protective coating, or the like. For example, the cover layer may be a plated film or material. The front surface electrode 2a can be protected from oxidation or the like by the cover layer. The cover layer may also function to alleviate the impact force that may be applied to the semiconductor element 2 during the bonding of the bonding wire 3. The cover layer may be, for example, a layer comprising nickel (Ni) or gold (Au). The cover layer may be an alloy or a layered structure including stacked films of materials. The semiconductor element 2 is bonded to the conductor pattern 12 on the front surface 11a side of the substrate 1 via a first bonding member 9 on the rear surface side (side opposite to the side on which the front surface electrode 2a is provided). As the first bonding member 9, for example, solder, a paste containing sintered silver particles, or the like can be used.

The semiconductor element 2 has, for example, a vertical structure in which a current flows from the front surface electrode 2a side to the rear surface side of the semiconductor element 2. Specifically, the semiconductor element 2 may be a switching element (such as an insulated gate bipolar transistor (IGBT) or a vertical metal oxide semiconductor field effect transistor (MOSFET)) or a rectifying element (such as a Schottky barrier diode). The semiconductor element 2 may be, for example, silicon (Si), silicon carbide (Sic), or gallium nitride (GaN).

The bonding wire 3 is bonded to the front surface electrode 2a at a bonding portion 31. In this context bonding portion 31 refers to a joint portion where the bonding wire 3 and the front surface electrode 2a are in contact with each other. A current flows to the front surface electrode 2a through the bonding wire 3. As the material of the bonding wire 3, aluminum or copper can be used.

The first sealing member 4 covers the outer periphery of the bonding portion 31 on the front surface electrode 2a. The first sealing member 4 may be in partial or full direct contact with the bonding portion 31, and the coverage is not limited full coverage. The thickness of the first sealing member 4 in the vertical direction may be greater or less than the dimension (e.g., wire diameter) of the bonding wire 3 at the bonding portion 31. In general, as the thickness of the first sealing member 4 in the vertical direction increases, the influence of the thermal stress on the first sealing member 4 provided by the bonding wire 3 increases, and the force applied to the first sealing member 4 increases. When the thermal stress applied from the bonding wire 3 to the first sealing member 4 increases, the first sealing member 4 may be more easily peeled off from the front surface electrode 2a. Therefore, the thickness of the first sealing member 4 in the vertical direction can be set to a thickness less than the dimension of the bonding wire 3 in some examples.

In general, in a semiconductor module, components such as the semiconductor element 2 and the conductor pattern 12 are sealed with a material having an insulating property so that there is no unnecessary electrical conduction between components or the like. However, since the second sealing member 5 may be used cover the outer peripheral portions of the first sealing member 4, even if the first sealing member 4 is conductive, unintended current will not flow to portions or components other than the semiconductor element 2. Therefore, the first sealing member 4 does not necessarily need to be made of an insulating material and, in some examples, a conductive material can be used for the first sealing member 4. In some examples, the first sealing member 4 can be insulating materials such as a polyimide resin, a resin comprising polyimide and silicone gel, an epoxy resin, a phenol resin, or the like. In some examples, the first sealing member 4 may comprise a resin incorporating a filler. The filler may be a conductive material in some examples. The filler may be a metal or a ceramic can be used. By incorporating the filler, it may be possible to improve the thermal conductivity and the electrical properties of the first sealing member 4. Inclusion of the filler may also allow for physical property values, such as hardness and the linear expansion coefficient, of the first sealing member 4 to be more easily varied as compared with the case when the filler is not used. It may be preferable that the first sealing member 4 has a glass transition temperature (T_{g}) higher than the maximum expected operating temperature of the semiconductor module 101. When silicon carbide (SiC), gallium nitride (GaN), or the like is used in the semiconductor element 2, the semiconductor element 2 can typically be operated at a higher temperature than when only silicon is used, and thus the temperature applied to the bonding portion 31 may also increase. Therefore, when SiC, GaN, or the like is used for the semiconductor element 2, it may be preferable that the first sealing member 4 has a glass transition temperature of 150° C. or higher.

The second sealing member 5 covers the otherwise exposed surface of the front surface electrode 2a. A part of the second sealing member 5 is in direct contact with the first sealing member 4. The second sealing member 5 may not cover the entire outer surface of first sealing member 4. The second sealing member 5 and the bonding wire 3 are not in direct contact with each other. As the second sealing member 5, a material having insulating properties and moisture resistance is preferably used. For example, the second sealing member 5 may be a resin comprising polyimide or silicone gel, an epoxy resin, a polyolefin-based resin, or a fluorine-based resin (fluoropolymer) can be used. In general, the second sealing member 5 needs to have a sufficient thickness to provide the required moisture resistance for protection of the front surface electrode 2a. For example, the thickness of the second sealing member 5 can be set to 50 μm or more. Here, “moisture resistance” refers to prevention or limiting of moisture in a high humidity environment from reaching (or affecting) the front surface electrode 2a. The higher the moisture resistance of the material, the more difficult it is for moisture to enter from the outside when in a high humidity environment or otherwise. For example, when the moisture resistance of the second sealing member 5 is referred to as low in this context, moisture that enters the inside of the semiconductor module 101 from a high humidity environment and causes the dielectric breakdown voltage of the second sealing member 5 to decrease. When the dielectric breakdown voltage of the second sealing member 5 is reduced, a leakage current is generated in the semiconductor element 2, which ultimately leads to breakdown.

The third sealing member 6 fills the semiconductor module 101 to seal the entire semiconductor element 2. Specifically, the third sealing member 6 fills the empty region outwardly defined by the base plate 7 and the case 8. The third sealing member 6 covers the insulating substrate 1, the semiconductor element 2, and the bonding wire 3. The third sealing member 6 may cover just the second sealing member 5 and the first sealing member 4, thus, the third sealing member 6 may not necessarily cover all of the insulating substrate 1, the semiconductor element 2, and the bonding wire 3. As the third sealing member 6, a material having insulating properties can be used. For example, a silicone gel can be used as the third sealing member 6.

Next, the relationship between the elastic modulus and the dielectric breakdown strength of the first sealing member 4, the second sealing member 5, and the third sealing member 6 will be described. Generally, with a semiconductor-based device, cycles of heating and cooling are repeated as the device is turned on and off. Since the thermal expansion coefficient of a bonding wire (e.g., bonding wire 3) and the thermal expansion coefficient of a surface electrode (e.g. front surface electrode 2a) to which the bonding wire is bonded are usually different from each other thermal stress due to the difference in thermal expansion coefficient during thermal cycling will be generated, and the bonding wire may thus be peeled off (separated) from the front surface electrode. After the separation of the bonding wire, the moisture-resistant resin covering the front surface electrode at the bonding between the front surface electrode and the bonding wire may also be peeled off. Whenever the bonding wire is separated off from the front surface electrode, the device may fail and thus reliability of the semiconductor device or module including such a device is reduced. In addition, if the moisture-resistant resin is peeled off, moisture absorbed into a silicone gel or the like covering the entire semiconductor device may now reach the front surface electrode, thereby reducing the reliability of the semiconductor device or module. Even if the bonding wire is not separated from the front surface electrode, the moisture-resistant resin itself may shrink due to the heat generated by the semiconductor-based device (e.g., semiconductor element 2), and thus the moisture-resistant resin may be peeled off from the front surface electrode.

Therefore, in the first embodiment, the first sealing member 4, the second sealing member 5, and the third sealing member 6 having different elastic moduli are used in a manner to act as a reinforcement of the bonding portion 31 between the front surface electrode 2a and the bonding wire 3. As the first sealing member 4, a material having a higher elastic modulus than the second sealing member 5 and the third sealing member 6 is used. The elastic modulus of the first sealing member 4 is desirably 1,000 MPa or more. The elastic modulus of the second sealing member 5 is lower than the elastic modulus of the first sealing member 4 but is higher than the elastic modulus of the third sealing member 6. The elastic modulus of the third sealing member 6 is lower than the elastic modulus of the second sealing member 5. For example, the elastic modulus of the third sealing member 6 may be set to 1 MPa or less. The member having the largest elastic modulus is the first sealing member 4, followed by the second sealing member 5, and then the third sealing member 6. In some examples, it can be sufficient that the elastic modulus of the sealing member closest to the bonding portion 31 is the largest while the elastic modulus of the sealing member at another position farther away from the bonding portion 31 is the lower. The number of types of different sealing members is not limited to three and may be two or more.

When the first sealing member 4 has a higher elastic modulus than the second sealing member 5, the first sealing member 4 can generally be considered to have better resistance to heat shrinkage than the second sealing member 5. Therefore, when the bonding portion 31 is sealed without including the first sealing member 4, the stress applied to the second sealing member 5 is increased. Therefore, inclusion of the first sealing member 4 serves to reduce or prevent peeling of the second sealing member 5 from the front surface electrode 2a. In addition, since the second sealing member 5 has a higher elastic modulus than the third sealing member 6, the second sealing member 5 can generally be considered to have better resistance to heat shrinkage than the third sealing member 6. That is, the semiconductor element 2 can be sealed with the different types of sealing members, each having different elastic moduli, and reliability and moisture resistance of the semiconductor module 101 can be maintained.

It is typically desirable that the second sealing member 5 and the third sealing member 6 have a higher dielectric breakdown strength than the first sealing member 4. In this context, the dielectric breakdown strength is an index value indicating how much voltage can be applied to an insulator before the insulator is broken down and loses its electrical insulating property to permit a current flow. In order to prevent current from flowing outside the semiconductor element 2 and the bonding wire 3, it is desirable that the second sealing member 5 and the third sealing member 6 have a higher dielectric breakdown strength than the first sealing member 4. For example, it is preferable that the second sealing member 5 and the third sealing member 6 have a dielectric breakdown strength of 10 kV (per 1 mm).

The base plate 7 has a role of permitting the heat generated from the semiconductor element 2 to flow to a heat sink or the like for removing the generated heat. The heat flowing to the heat sink is ultimately removed to the outside of the semiconductor module 101 in this first embodiment via the heat sink. The base plate 7 has a front surface 7a and a rear surface 7b.

As the base plate 7, a material having high thermal conductivity can be used. For example, aluminum or copper can be used as the base plate 7. The front surface 7a is bonded to conductor pattern 12 provided on the rear surface 11b side of the insulating substrate 1. The base plate 7 can be bonded to the conductor pattern 12 via a second bonding member 10. As the second bonding member 10, solder, sintered silver particles, or the like can be used.

The case 8 has a side wall 81 and an inner wall 82. The case 8 is bonded to a side surface 71 of the base plate 7 at the inner wall 82. As the case 8, polyphenylene sulfide (PPS), polybutylene terephthalate (PBT), or the like can be used. The base plate 7 and the case 8 form the outer housing of the semiconductor module 101.

Next, a method for manufacturing the semiconductor module 101 will be described. FIG. 2 is a flowchart illustrating aspects of a method for manufacturing the semiconductor module 101 according to the first embodiment.

In step S1, the semiconductor element 2 is bonded to the insulating substrate 1. Specifically, the rear surface of the semiconductor element 2 is bonded to the conductor pattern 12 on the front surface 11a side of the insulating substrate 1 via the first bonding member 9. Next, the process proceeds to step S2.

In step S2, the bonding wire 3 is bonded (joined) to the front surface electrode 2a of the semiconductor element 2 by ultrasonic bonding or the like. After the bonding wire 3 is bonded to the front surface electrode 2a, the process proceeds to step S3.

In step S3, the first sealing member 4 is supplied so as to cover the bonding portion 31, and the bonding portion 31 is thus sealed with the first sealing member 4. FIGS. 3A and 3B show schematic views of an enlarged cross section of a part of the semiconductor module 101 at step S3 of the method for manufacturing the semiconductor module 101 according to the first embodiment.

As shown in FIG. 3A, the first sealing member 4 is supplied as liquid (flowable material) in the vicinity of the bonding portion 31. In this context, the vicinity of the bonding portion 31 refers to approximately the height of the wire on the front surface electrode 2a or within about a diameter of the wire in any direction in the plane of the front surface electrode 2a. The first sealing member 4 can reach the bonding portion 31 as a droplet and may spread or coalesce by surface tension, or the like. In general, the droplet or liquid can be applied from any position as long as the bonding portion 31 can be covered by the first sealing member 4. The first sealing member 4 can be supplied to the bonding portion 31 dropwise as a resin precursor material such as a mixture of a main curable component and a curing agent or as a solution mixture comprising a main component in a solvent. The material can be applied using air dispensing or jet dispensing (e.g., inkjet-type dispensing). In other examples, when the first sealing member 4 comprises a solder alloy, molten solder can be supplied to the bonding portion 31 using a soldering iron or the like.

After the first sealing member 4 is supplied to the bonding portion 31, the supplied first sealing member 4 is cured or otherwise solidified. When the first sealing member 4 is a resin, the first sealing member 4 can be cured. For example, the supplied liquid first sealing member 4 may be held at room temperature for fixed amount of time or longer or by heating to an elevated temperature that is lower than the melting point of the first bonding member 9. When the first sealing member 4 is a solder alloy, the first sealing member 4 cures when the supplied liquid first sealing member 4 (solder) cools. As shown in FIG. 3B, the bonding portion 31 is covered by the first sealing member 4 after the curing of the supplied first sealing member 4. After the bonding portion 31 is sealed with the first sealing member 4, the process proceeds to step S4.

In step S4, the second sealing member 5 is supplied onto the surface of the front surface electrode 2a. The second sealing member 5 contacts the first sealing member 4 and covers the surface of the front surface electrode 2a and at least a portion of the side surface of the first sealing member 4.

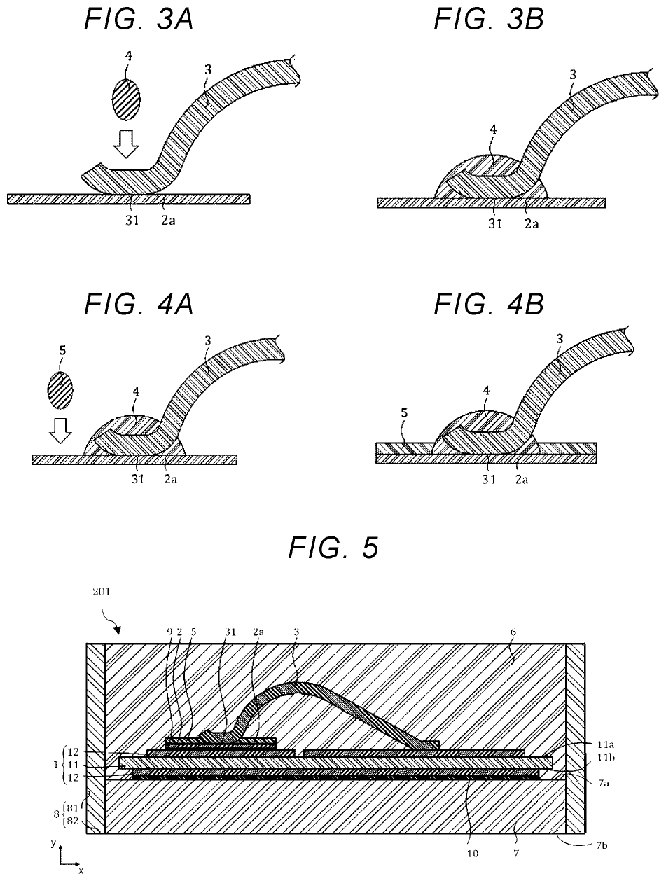

FIGS. 4A and 4B show schematic views of an enlarged cross section of a part of the semiconductor module at step S4 of the method for manufacturing the semiconductor module 101 according to the first embodiment. As shown in FIG. 4A, the second sealing member 5 is supplied to the front surface electrode 2a of the semiconductor element 2 as a liquid. The second sealing member 5 contacts the first sealing member 4 applied in step S3. In this example, the coating start position for the second sealing member 5 is not limited to being near the vicinity of the end portion of the bonding wire 3, and the second sealing member 5 can be applied from above the front surface electrode 2a at any position outside the bonding portion 31 from the vertical direction. If the liquid precursor of the second sealing member 5 was applied from above the bonding portion 31, the second sealing member 5 and the bonding wire 3 might come into contact with each other, and thus thermal stress due to heat shrinkage of the second sealing member 5 would be applied to the bonding wire 3. In order to avoid this, the second sealing member 5 is preferably applied from above the front surface electrode 2a at position not overlapping with the bonding portion 31 from the vertical direction. When the second sealing member 5 is a resin, the second sealing member 5 can be supplied onto the front surface electrode 2a in a manner similar to the first sealing member 4, such as dropwise as a resin precursor material comprising a mixture of a main curable component and a curing agent or as a solution mixture of a main component in a solvent. The second sealing member 5 can be applied using air dispensing or jet dispensing.

After the second sealing member 5 is supplied to the front surface electrode 2a, the supplied second sealing member 5 is cured or otherwise solidified.

When the second sealing member 5 is a resin, the second sealing member 5 can be cured. For example, the supplied liquid second sealing member 5 may be held at room temperature for fixed amount of time or longer or by heating to an elevated temperature that is lower than the melting point of the first bonding member 9. As shown in FIG. 4B, after the front surface electrode 2a is covered with the second sealing member 5, the process proceeds to step S5.

In step S5, the insulating substrate 1 is bonded to the base plate 7. The base plate 7 is bonded to the conductor pattern 12 of the insulating substrate 1 via the second bonding member 10. A case 8 may be provided in this step such that the inner wall 82 of the case 8 and the side surface 71 of the base plate 7 are in contact with each other. The outer housing of the semiconductor module 101 is formed by the base plate 7 and the case 8. After bonding the insulating substrate 1 to the base plate 7, the process proceeds to step S6.

In step S6, the third sealing member 6 is supplied into the housing of the semiconductor module 101. That is, the space above the base plate 7 inside the case 8 is filled the third sealing member 6. The third sealing member 6 can be supplied into the housing of the semiconductor module 101 as liquid, then cured or otherwise solidified.

Next, certain advantages of a semiconductor module according to the first embodiment will be described. In the first embodiment, at the bonding portion 31 between the front surface electrode 2a and the bonding wire 3, the difference between the thermal expansion coefficient of the semiconductor element 2 (with the front surface electrode 2a) and the bonding wire 3 causes thermal stress. The thermal stress repeatedly occurs with energization cycles. FIG. 5 shows a cross-sectional view of a semiconductor module according to a comparative example. The bonding portion 31 of the semiconductor module 201 shown in FIG. 5 is sealed with just the second sealing member 5 (i.e., no first sealing member 4 is used). In contrast, the bonding portion 31 of the semiconductor module 101 shown in FIG. 1 is first sealed with the first sealing member 4 before the second sealing member 5 is applied. The first sealing member 4 has a higher elastic modulus than the second sealing member 5. Therefore, when the bonding portion 31 is sealed with the first sealing member 4, the stress from the bonding wire 3 applied to the bonding portion 31 can be reduced as compared with a case where the bonding portion 31 is sealed directly with the second sealing member 5. However, by reducing the stress applied to the bonding portion 31 by inclusion of the first sealing member 4, it is possible to better prevent the peeling of the bonding wire 3 from the front surface electrode 2a. That is, according to the semiconductor module 101 according to the first embodiment, it is possible to provide a semiconductor module having higher reliability.

The first sealing member 4, the second sealing member 5, and the third sealing member 6 repeatedly thermally expand and shrink due to the heat generation/removal cycle of the semiconductor element 2, and thermal stress is thus generated. The second sealing member 5 provides moisture resistance, so generally the greater the thickness in the vertical direction of the second sealing member 5, the more difficult it is for moisture to enter from the third sealing member 6 and to reach the bonding portion 31. However, as the thickness of the second sealing member 5 increases, the influence of the thermal stress on the bonding wire 3 from the second sealing member 5 increases, and the force applied to the bonding portion 31 of the bonding wire 3 increases.

In the semiconductor module 101 according to the first embodiment, since the first sealing member 4 covers the bonding portion 31, the thermal stress applied from the second sealing member 5 can be mitigated.

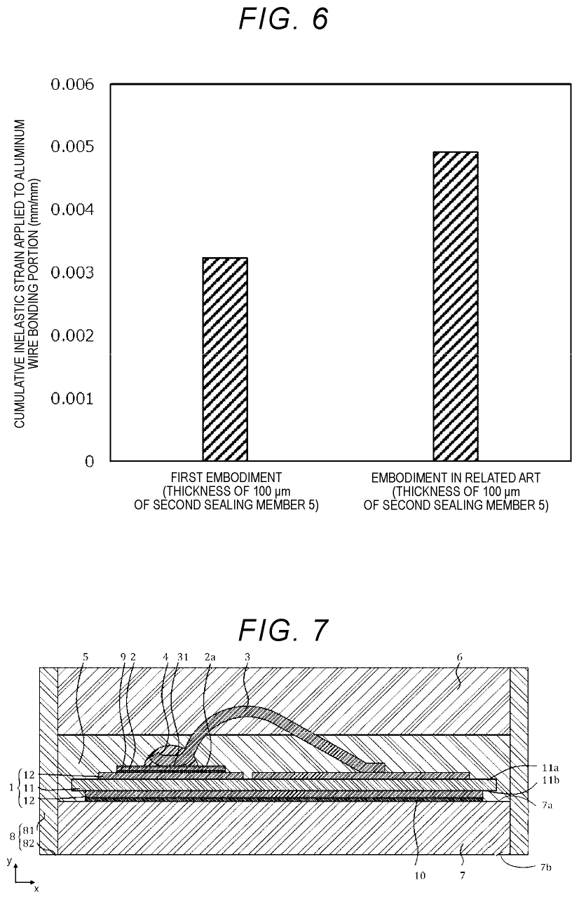

FIG. 6 depicts a graph providing a comparison of the cumulative inelastic strain applied to the bonding portion 31 of the bonding wire 3 according to the first embodiment to the same in the comparative example such as depicted in FIG. 5. Using a finite element method, a comparison made between the cumulative inelastic strain applied to the vicinity of the bonding portion 31 of the semiconductor module 101 shown in FIG. 1 and the cumulative inelastic strain applied to the vicinity of the bonding portion 31 of the semiconductor module 201 shown in FIG. 5. Specifically, the depicted comparison of the cumulative inelastic strain (mm/mm) applied to the bonding portion 31 is for one thermal cycle simulating a power cycle test in which the current is turned on for 2 seconds and then turned off for 8 seconds. In these examples, the thickness of the second sealing member 5 in the semiconductor module 101 and the semiconductor module 201 was set to 100 μm. Also, for the semiconductor module 101 and the semiconductor module 201, the diameter of the bonding wire 3 was set to Φ400 μm.

As shown in FIG. 6, it can be seen that the cumulative inelastic strain applied to the bonding portion 31 in the semiconductor module 101 (with first sealing member 4) is less than in the semiconductor module 201 (no first sealing member 4) by about 35%. That is, according to the semiconductor module 101 according to the first embodiment, even when the second sealing member 5 is thick, it is possible to prevent the peeling of the bonding portion 31 from the front surface electrode 2a and the peeling of the second sealing member 5 from the front surface electrode 2a, which are caused by the inelastic strain. That is, it is possible to provide a semiconductor module 101 in which the bonding portion 31 is reinforced while still ensuring the moisture resistance reliability of the semiconductor element 2.

In general, as the thickness of the first sealing member 4 in the vertical direction becomes smaller, the portion of the bonding wire 3 to which the stress due to the heat shrinkage of the first sealing member 4 is applied is reduced. Therefore, it is possible to provide a semiconductor module in which the bonding wire 3 is less likely to peel off from the front surface electrode 2a.

### Second Embodiment

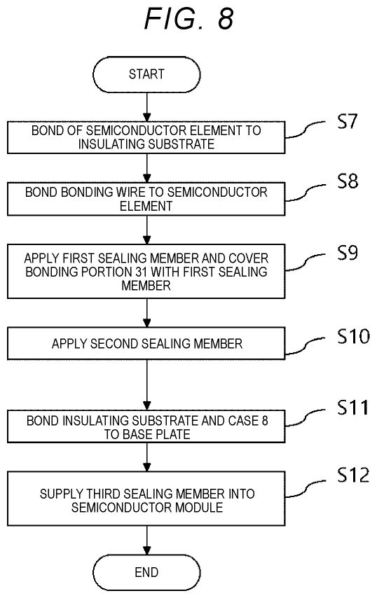

Next, a semiconductor module and a method for manufacturing a semiconductor module according to a second embodiment will be described with reference to FIGS. 7 and 8. In the second embodiment, the structure of the second sealing member 5 is different from that of the first embodiment.

In the semiconductor module 101 according to the first embodiment, the second sealing member 5 contacts the front surface electrode 2a and the first sealing member 4. However, in the semiconductor module according to the second embodiment, as depicted in FIG. 7, the second sealing member 5 is also contacts device portions other than the front surface electrode 2a and the first sealing member 4. FIG. 7 shows a cross-sectional view of a semiconductor module according to the second embodiment. As shown in FIG. 7, the second sealing member 5 in the second embodiment contacts the insulating substrate 1 and the base plate 7 in addition to the front surface electrode 2a of the semiconductor element 2. That is, when initially applied, the second sealing member 5 spread beyond the front surface electrode 2a, and thus the thickness of the second sealing member 5 in the vertical direction can also be greater than when the second sealing member 5 is limited to covering only on the front surface electrode 2a (as in the first embodiment).

FIG. 8 shows a flowchart of a method for manufacturing a semiconductor module according to the second embodiment. Step S7, step S8, and step S9 can be performed in the same manner as described for steps S1 to S3 with respect to FIG. 2. In step S9, after the bonding portion 31 has been sealed with the first sealing member 4, the process proceeds to step S10.

In step S10, the second sealing member 5 is supplied onto the front surface electrode 2a to cover and seal the front surface electrode 2a. At this time in step S10, the second sealing member 5 is also supplied to positions outside (beyond) the front surface electrode 2a. Therefore, the coating start position of the second sealing member 5 in step S10 is not limited to being above the front surface electrode 2a at a position not above the bonding portion 31 in the vertical direction. The second sealing member 5 can be applied from any position including those not above the front surface electrode 2a. After the front surface electrode 2a is covered with the second sealing member 5, the process proceeds to step S11.

Step S11 and step S12 can be performed in the same manner as described for step S5 and step S6 with respect to FIG. 2.

In general, the greater the thickness of the second sealing member 5, the greater the thermal stress applied to the bonding portion 31 and the second sealing member 5 in the vicinity of the bonding portion 31. However, since the first sealing member 4 covers the bonding portion 31, it is possible to reduce the thermal stress applied to the bonding portion 31 and the second sealing member 5 in the vicinity of the bonding portion 31. Therefore, according to the semiconductor module of the second embodiment, the amount of the second sealing member applied can be increased, and the thickness of the second sealing member 5, which is a moisture-resistant resin, can be increased. That is, according to the semiconductor module of the second embodiment, it is possible to provide reliability of the bonding portion 31 is ensured while further limiting moisture from reaching the semiconductor element 2, thus the moisture resistance reliability of the semiconductor element 2 will be high.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a semiconductor element on a substrate, a first surface of the semiconductor element facing away from the substrate and a second surface facing the substrate;
a first surface electrode on the first surface of the semiconductor element;
a bonding wire connected to the first surface electrode at a bonding portion;
a first sealing member covering the bonding portion;
a second sealing member covering a portion of the first surface electrode outside the bonding portion; and
a third sealing member covering the first sealing member and the second sealing member.

2. The semiconductor device according to claim 1, wherein the elastic modulus of the first sealing member is higher than the elastic modulus of the second sealing member and the elastic modulus of the third sealing member.

3. The semiconductor device according to claim 2, wherein the second sealing member has a higher moisture resistance than the third sealing member.

4. The semiconductor device according to claim 3, wherein a thickness of the first sealing member is greater than a diameter of the bonding wire.

5. The semiconductor device according to claim 4, wherein a thickness of the second sealing member is less than the thickness of the first sealing member.

6. The semiconductor device according to claim 4, wherein
a thickness of the second sealing member is greater than the thickness of the first sealing member,
the second sealing member fully covers the first sealing member,
the third sealing member contacts the second sealing member, and
the third sealing member does not contact the first sealing member.

7. The semiconductor device according to claim 1, wherein the first sealing member is solder.

8. The semiconductor device according to claim 7, wherein the second sealing member is a first-type resin.

9. The semiconductor device according to claim 8, wherein the third sealing member is a second-type resin different from the first-type resin.

10. The semiconductor device according to claim 1, wherein the first sealing member is a resin.

11. The semiconductor device according to claim 1, wherein the second sealing member covers the first sealing member.

12. A semiconductor module, comprising:
a housing; and
a semiconductor device in the housing, the semiconductor device includes:
a semiconductor element on a substrate, a first surface of the semiconductor element facing away from the substrate and a second surface facing the substrate;
a first surface electrode on the first surface of the semiconductor element;
a bonding wire connected to the first surface electrode at a bonding portion;
a first sealing member covering the bonding portion;
a second sealing member covering a portion of the first surface electrode outside the bonding portion; and
a third sealing member covering the first sealing member and the second sealing member.

13. The semiconductor module according to claim 12, wherein the elastic modulus of the first sealing member is higher than the elastic modulus of the second sealing member and the elastic modulus of the third sealing member.

14. The semiconductor module according to claim 13, wherein the second sealing member has a higher moisture resistance than the third sealing member.

15. The semiconductor module according to claim 14, wherein a thickness of the first sealing member is greater than a diameter of the bonding wire.

16. The semiconductor module according to claim 15, wherein a thickness of the second sealing member is less than the thickness of the first sealing member.

17. The semiconductor module according to claim 15, wherein a thickness of the second sealing member is greater than the thickness of the first sealing member,
the second sealing member fully covers the first sealing member,
the third sealing member contacts the second sealing member, and
the third sealing member does not contact the first sealing member.

18. A method for manufacturing a semiconductor module, the method comprising:
bonding a bonding wire to a first surface electrode on a semiconductor element, the semiconductor element being on a substrate and having a first surface facing away from the substrate and a second surface facing the substrate, the first surface electrode being on the first surface of the semiconductor element;
applying a first sealing member to cover a bonding portion between the first surface electrode and the bonding wire;
applying a second sealing member to cover a portion of the first surface electrode outside the bonding portion; and
applying a third sealing member to cover the first sealing member and the second sealing member.

19. The method according to claim 18, wherein the elastic modulus of the first sealing member is higher than the elastic modulus of the second sealing member and the elastic modulus of the third sealing member.

20. The method according to claim 18, wherein the second sealing member covers the first sealing member.
